(19) United States
(12) Patent Application Publication
(10) Pub. No.: US 2013/0181581 A1
(43) Pub. Date: Jul. 18, 2013

(54) Piezoelectric Multilayer Actuator

(71) Applicants: Marion Ottlinger, Deutschlandsberg (AT); Reinhard Gabl, St. Peter (AT); Martin Galler, Graz (AT); Andreas Stani, Leibnitz (AT)

(72) Inventors: Marion Ottlinger, Deutschlandsberg (AT); Reinhard Gabl, St. Peter (AT); Martin Galler, Graz (AT); Andreas Stani, Leibnitz (AT)

(73) Assignee: EPCOS AG, Muenchen (DE)

(21) Appl. No.: 13/809,350

(22) PCT Filed: Jul. 29, 2011
(86) PCT No.: PCT/EP11/63123

§ 371 Date: Mar. 28, 2013

(30) Foreign Application Priority Data
Jul. 30, 2010 (DE) 10 2010 032 810.3
Oct. 26, 2010 (DE) 10 2010 049 574.3

(51) Int. Cl. H01L 41/047; H01L 41/083

(52) U.S. Cl. CPC H01L 41/0472; H01L 41/0477; H01L 41/083
USPC 310/363; 310/365

(57) ABSTRACT

A piezoelectric multilayer actuator includes a stack of piezoelectric layers arranged one above another and first electrode layers and second electrode layers arranged alternately one above another between said piezoelectric layers. The electrode layers extend into the stack from a first and a second lateral face of the stack and overlapping in the stack. The first lateral face holds a first contact element in electrical contact with the first electrode layers and the second lateral face (5) holds a second contact element in electrical contact with the second electrode layers. The first and second contact elements each have a wire mesh, wherein at least one wire mesh has a twill-weave structure.

This patent application is a national phase filing under section 371 of PCT/EP2011/063123, filed Jul. 29, 2011, which claims the priority of German patent application 10 2010 032 810.3, filed Jul. 30, 2010, and German patent application 10 2010 049 574.3, filed Oct. 26, 2010, each of which is incorporated herein by reference in its entirety.

### TECHNICAL FIELD

A piezoelectric multilayer actuator comprising a stack composed of piezoelectric layers and electrode layers arranged therebetween is specified.

### BACKGROUND

German patent document DE 10 2006 026 643 A1 describes a piezoelectric actuator.

### SUMMARY OF THE INVENTION

In at least some embodiments, a piezoelectric multilayer actuator comprises a contact element which allows electrical contact to be made as reliably and cost-effectively as possible.

A piezoelectric multilayer actuator in accordance with at least one embodiment comprises, in particular, a stack composed of piezoelectric layers arranged one above another and first electrode layers and second electrode layers arranged alternately one above another between said piezoelectric layers, said electrode layers extending into the stack from a first and a second side area of the stack and overlapping in the stack. Furthermore, on the first side area, a first contact element is arranged in electrical contact with the first electrode layers and, on the second side area, a second contact element is arranged in electrical contact with the second electrode layers.

When producing a reliable electrical contact between the electrode layers of piezoelectric multilayer actuators that are embodied as internal electrodes and the electrodes of an electrical driving device, the technical difficulties are inter alia, that the contact-making in the form of the first and second contact elements ought not to be damaged by the frequent deflection of the piezoelectric multilayer actuator, that is to say typically more than 10⁹ deflections, for example, when the piezoelectric multilayer actuator is used in injection systems of engines, and the contact-making should have as little influence as possible on the movements of the piezoelectric multilayer actuator. The problem of realizing reliable contact-making is aggravated particularly by high levels of elongation occurring in the region in proximity to cracks in the piezoelectric multilayer actuators. In addition, depending on the intended use, sometimes there are stringent requirement for the contact-making with regard to thermal stability, avoiding contamination and prior damage to the piezoelectric multilayer actuator as a result of implementing the contact-making, and with regard to low costs for material and process. In many applications, furthermore, a slim, that is to say space-saving, design of the contact-making can be necessary or advantageous.

There are a large number of different technological concepts for externally making contact with a multilayer piezoactuator. One typical concept resides, for example, in fixing a so-called wire harp by means of soft soldering on the outer metallization. However, this type of contact-making is disadvantageously associated with a high space requirement and contamination with flux. Furthermore, solder contacts are known which are intended to satisfy very specific design specifications with regard to material, construction (e.g., pin at wire harp, screen or metal sheet), geometry or the like. Furthermore, by way of example, welding contacts are also known.

In accordance with one particularly preferred embodiment of the piezoelectric multilayer actuator described here, the contact elements each have a wire fabric. Here and hereinafter, the wire fabric can also be designated as wire braiding.

In accordance with a further embodiment, the first and second contact elements, as a result of the respective wire fabric, have a flexible construction for making contact with the first and second electrode layers.

In this case, the arrangement of the first and second contact elements on the stack of the piezoelectric layers can be effected by means of soldering, for example. An electrical contact layer can respectively be arranged on the first and second side areas, for example, wherein the first and second contact elements are in each case fixed on one of the electrical contact layers, for instance by soldering. By way of example, when applying such an electrical contact layer, it is also called a base metallization, a metal paste is printed onto the first and second side areas, subsequently dried and finally fired. A solder, for example a copper-tin solder, can be used for soldering the contact elements onto the contact layers.

In accordance with a further embodiment, a contact pin for further contact-making is integrated into at least one or in each case into one of the two wire fabrics. By way of example, such a contact pin, which can for example also be formed by a multiple-stranded wire, a pin or an expanded metal, is mechanically and electrically connected to the wire fabric by soldering or welding. Preferably, the first and respectively second contact element and the contact pin integrated into the wire fabric of the contact element are applied to the stack composed of piezoelectric layers and electrode layers arranged therebetween in a common soldering step.

In accordance with a further embodiment, the contact elements can in each case comprise a woven or braided metal strip or a woven or braided metal wire.

The inventors have discovered that the material properties of the contact elements, that is to say the properties of the corresponding fabric of the wire, crucially determine the fault mode and the lifetime of the piezoelectric multilayer actuator. This may apply, in particular, to those actuator applications that require high levels of elongation. Furthermore, the coefficient of thermal expansion and/or the modulus of elasticity, also designated as the elastic modulus, can advantageously be adapted to the corresponding properties of the stack of piezoelectric layers, which stack can comprise, for example, a suitable piezoelectric ceramic material.

In addition, properties of the first and second contact elements such as tensile strength, elongation at break and tensile yield point may advantageously prove to be important parameters. Furthermore, it may also be possible, for example, that the lifetime of the piezoelectric multilayer actuator can advantageously be increased in comparison with known contact-making possibilities with an unchanged wire composition merely by virtue of the type of mesh composite.

In accordance with one embodiment, at least one of the wire fabrics of the first and second contact elements has a linen weave, which can also be designated as plain weave or tabby weave.

In accordance with a further, particularly preferred embodiment, at least one wire fabric has a twill weave. If the mesh composite is chosen to be looser, for example by virtue of a twill weave instead of a linen weave, lower wire loading can occur during wire production and upon elongation in the area of application.

In accordance with a further embodiment, the at least one wire fabric has a modulus of elasticity of 200000 MPa.

In accordance with a further embodiment, the at least one wire fabric has a tensile strength of greater than or equal to 500 N/mm², wherein here and hereinafter the limits of specified ranges are concomitantly included in each case. In various tests with regard to reliability in the application of piezoelectric multilayer actuators, the inventors have discovered that by using wire fabrics having, inter alia, a tensile strength of greater than or equal to 500 N/mm², the lifetime of multilayer actuators can be significantly increased in comparison with multilayer actuators having contact elements composed of wire fabrics having a lower tensile strength.

Preferably, the at least one wire fabric has a tensile strength of greater than or equal to 500 N/mm² and less than or equal to 850 N/mm².

In a further embodiment, the at least one wire fabric has a tensile strength of greater than or equal to 500 N/mm² and less than or equal to 700 N/mm². In a further embodiment, the wire fabrics of the contact elements have a tensile strength of greater than or equal to 650 N/mm² and less than or equal to 850 N/mm².

In accordance with a further embodiment, the at least one wire fabric has a tensile yield point of greater than or equal to 380 N/mm². In a further embodiment, the at least one wire fabric has a tensile yield point of greater than or equal to 380 N/mm² and less than or equal to 550 N/mm².

In accordance with a further embodiment, the at least one wire fabric has an elongation at break of greater than or equal to 20%. In various tests with regard to the reliability of the contact-making of a piezoelectric multilayer actuator in the case of high mechanical stressing it was found that contact elements composed of wire fabrics having an elongation at break of greater than or equal to 20% achieve particularly good results.

In a further embodiment, the at least one wire fabric has an elongation at break in the range of 30 to 35%.

In accordance with a further embodiment, the at least one wire fabric has a coefficient of thermal expansion of greater than or equal to 1.1×10⁻⁵. The inventors have discovered that by using wire fabrics having, inter alia, a coefficient of thermal expansion of greater than or equal to 1.1×10⁻⁵, the susceptibility to failure of the contact-making of the piezoelectric multilayer actuator can be significantly reduced.

In a further embodiment, the at least one wire fabric has a coefficient of thermal expansion of greater than or equal to 1.1×10⁻⁵ and less or equal to 1.60×10⁻⁵.

In accordance with a further embodiment, the at least one wire fabric has a mesh width of greater than or equal to 0.1 mm and less than or equal to 0.3 mm. A mesh width of greater than or equal to 0.15 mm and less than or equal to 0.2 mm, for example of 0.18 mm, can prove to be particularly advantageous.

In accordance with a further embodiment, the at least one wire fabric has a wire thickness of greater than or equal to 0.03 mm and less than or equal to 0.3 mm, preferably of greater than or equal to 0.02 and less than or equal to 0.1. By way of example, a wire thickness of 0.056 mm or 0.080 mm can prove to be particularly advantageous.

In equivalence with a further embodiment, the ratio of wire thickness to mesh width of the at least one wire fabric is in a range of between 0.3 and 0.45. It has been found that wire fabrics in which the ratio of wire thickness to mesh width is in the abovementioned range have particularly low wire loading during use of the piezoelectric multilayer actuator.

Preferably, the distance between in each case two first electrode layers directly adjacent to one another or in each case two second electrode layers directly adjacent to one another in the stack of the piezoelectric multilayer actuator is in a range of 60 to 65 μm, and particularly preferably 62 μm.

In accordance with a further embodiment, the ratio of the mesh width to a distance between in each case two first electrode layers directly adjacent to one another or in each case two second electrode layers directly adjacent to one another is in a range of between 2.5 and 3.5. As a result, firstly a flexible construction of the contact elements and secondly reliable contact-making of the piezoelectric multilayer actuator can be achieved.

In accordance with a further embodiment, the at least one wire fabric comprises an austenitic stainless steel.

In accordance with a further embodiment, the at least one wire fabric comprises a nickel-chromium alloy. In this case, the at least one wire fabric can particularly preferably comprise a nickel-chromium alloy having a ratio of nickel to chromium of 80 to 20.

In accordance with a further embodiment, the wire fabrics of the first and second contact elements have identical features and/or combinations of identical features of the abovementioned embodiments. Preferably, the first and second contact elements are embodied identically.

The piezoelectric multilayer actuator described here advantageously has a special and flexible construction of the contact-making for piezoelectric multilayer actuators which advantageously makes possible relative movements, for example local relative movements, between the piezoelectric multilayer actuator and the components for further contact-making. It may thus be possible to solve the problem of high mechanical stressing of the contact-making by large axial elongation of the piezoelectric multilayer actuator by material properties of the wire such as, for instance, increasing the tensile yield point and/or tensile strength, and alternatively or additionally by a looser mesh composite, in a manner that can be realized effectively and technically simply.

### BRIEF DESCRIPTION OF THE DRAWINGS

Further advantages and advantageous embodiments of the piezoelectric multilayer actuator specified will become apparent from the embodiments described below in conjunction with FIGS. 1 to 4.

FIG. 1 shows a schematic view of a piezoelectric multilayer actuator in accordance with one exemplary embodiment;

FIG. 2 shows a force-elongation diagram for various wire fabrics; and

FIGS. 3 and 4 each show a stack composed of piezoelectric layers and electrodes arranged therebetween.

### DETAILED DESCRIPTION OF ILLUSTRATIVE EMBODIMENTS

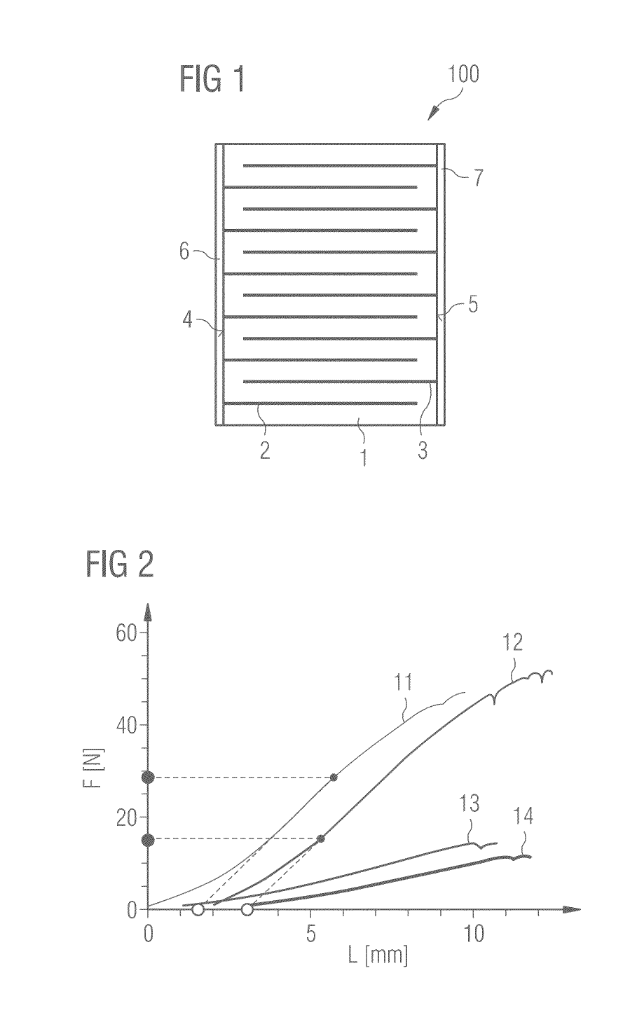

FIG. 1 shows a piezoelectric multilayer actuator 100 in accordance with one exemplary embodiment, comprising a stack 1 composed of piezoelectric layers arranged one above another and first electrode layers 2 and second electrode layers 3 arranged alternately one above another between said piezoelectric layers. The first and second electrode layers 2, 3 extend into the stack 1 from a first side area 4 and a second side area 5 of the stack 1 and overlap in the stack 1. On the first side area 4 of the stack 2, a first contact element 6 is arranged in electrical contact with the first electrode layers 2 and, on the second side area 5 of the stack 2, a second contact element 7 is arranged in electrical contact with the second electrode layers 3. The contact elements 6, 7 in each case have a wire fabric.

The two contact elements 6, 7 can be respectively fixed on a contact layer (not shown) printed onto the first and second side areas 4, 5 of the stack 2. In this case, the contact layers are applied to the side areas 4, 5 of the stack 2 for example in the form of a metal paste, subsequently dried and then fired. The fixing of the contact elements 6, 7 on the contact layer is preferably effected by soldering.

Furthermore, a contact pin (not shown) for further contact-making can be integrated into at least one of the two wire fabrics, particularly preferably in each case one contact pin into both wire fabrics. By way of example, such a contact pin, which can be formed by a contact pin or a multiple-stranded wire, for instance, is mechanically and electrically connected to the wire fabric by soldering or welding.

At least one of the wire fabrics of the contact elements 6, 7 is woven or braided in a twill weave. The advantage of a twill weave is manifested by a smaller mesh composite for example in comparison with a linen or plain weave. In the case of a twill weave, the wire is subjected to lower loading already during weaving.

FIG. 2 furthermore shows the difference in the force-elongation diagram between wire fabrics, which can also be designated as screens, having tabby weave, that is to say a plain weave, compared with wire fabrics having twill weave. In this case, the elongation distance L in mm is plotted on the horizontal axis and the force F to be applied in N is plotted on the vertical axis. The force-elongation curves of the wire fabrics having a tabby weave are designated by 11 and 12, and those of the wire fabrics having twill weave are designated by 13 and 14. As can be seen in FIG. 2, the force to be applied for an elongation distance of 5 mm is approximately 10 times lower in the case of a twill weave in comparison with a tabby weave. The looser mesh composite thus proves to be more elastic.

It proves to be particularly advantageous in the exemplary embodiment shown if both wire fabrics have a twill weave.

Furthermore, it is particularly advantageous if at least one of the two wire fabrics or else both has or have at least one or more of the following features:
a modulus of elasticity of 200000 MPa,|
a tensile strength of greater than or equal to 500 N/mm² and less than or equal to 850 N/mm²,
a tensile yield point of greater than or equal to 380 N/mm² and less than or equal to 550 N/mm²,
an elongation at break of greater than or equal to 30% and less than or equal to 35%,
a coefficient of thermal expansion of greater than or equal to 1.36×10⁻⁵ and less than or equal to 1.60×10⁻⁵,
a wire thickness of greater than or equal to 0.03 mm and less than or equal to 0.3 mm,
a mesh width of greater than or equal to 0.1 mm and less than or equal to 0.3 mm,
a ratio of wire thickness to mesh width in a range of between 0.3 and 0.45.

Furthermore, the distance between in each case two first electrode layers 2 directly adjacent to one another or in each case two second electrode layers 3 directly adjacent to one another is preferably in a range of 60 to 65 μm, and particularly preferably approximately 62 μm.

It is furthermore advantageous if the ratio of the mesh width of at least one wire fabric to the distance between in each case two first electrode layers 2 directly adjacent to one another or in each case two second electrode layers 3 directly adjacent to one another is in a range of between 2.5 and 3.5.

In particular, combinations of the abovementioned features for at least one or both wire fabrics can also be particularly advantageous. Inter alia, a first and a second contact element 6, 7 which have the combination of features designated below as exemplary embodiment A have proved to be particularly advantageous. Both contact elements 6, 7 have a wire fabric with twill weave composed of an austenitic stainless steel. Furthermore, wire fabrics have a modulus of elasticity of 200000 MPa, a tensile strength of greater than or equal to 500 N/mm² and less than or equal to 700 N/mm², and a tensile yield point of 380 N/mm². The elongation at break of the wire fabrics of the contact elements 6, 7 is greater than or equal to 30% and less than or equal to 35% and their coefficient of thermal expansion is 1.60×10⁻⁵. Furthermore, the mesh width of the wire fabrics is 0.18 mm and the wire thickness is 0.056 mm.

In accordance with a further exemplary embodiment which proved to be particularly advantageous, and which is designated below as exemplary embodiment B, the wire fabrics of the contact elements 6, 7 comprise a nickel-chromium alloy, wherein the ratio of nickel to chromium is 80 to 20. The wire fabrics of the contact elements 6, 7 have a modulus of elasticity of 200000 MPa, a tensile strength of greater than or equal to 650 N/mm² and less than or equal to 850 N/mm² and a tensile yield point of 550 N/mm². The elongation at break of the wire fabrics of the contact elements 6, 7 is 30% and the coefficient of thermal expansion is 1.36×10⁻⁵. The mesh width of the wire fabrics of the contact elements 6, 7 is 0.18 mm and the wire thickness is 0.080 mm.

Various energy-controlled tests are necessary for verifying reliability in the application of the piezoelectric multilayer actuators. Overload tests are usually carried out at a frequency of 83 Hz and a temperature of 80° C. and with an elongation of up to 2.4%.

It has been discovered that the use of a customary wire material, having a lower tensile strength and a lower elongation at break in comparison with the wire materials of exemplary embodiments A and B, can lead to a failure of the piezoelectric layers starting from 2×10⁸ cycles. Such a failure can be caused, for example, by a longitudinal crack in the piezoelectric layers between two predetermined breaking locations in the region of a so-called isozone, wherein the regions within the stack 1 in which the respectively opposite first and second electrode layers 2, 3 do not overlap are designated as isozones.

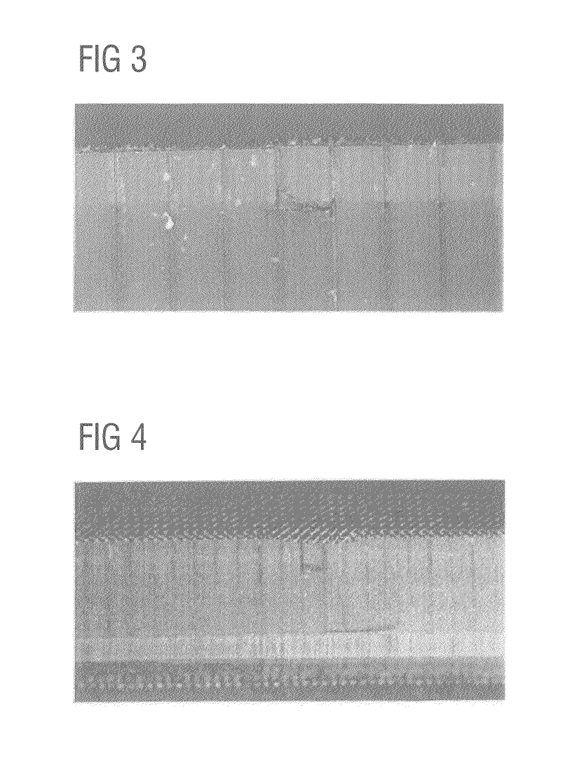

FIGS. 3 and 4 show such failures as a result of damage in the piezoelectric layers. The failure is determined by a decrease in capacitance or deflection since a stack segment is short-circuited.

In the driven thermal cycling test, in which a stack composed of piezoelectric layers which is contact-connected with a customary wire fabric composed of a wire material having a lower tensile strength and a lower elongation at break in comparison with the wire materials of exemplary embodiments A and B is operated alternately at −40° C. and +170° C. with an elongation of more than 1.5%, screen cracks typically appear as the cause of a fault after just a few temperature cycles.

In reliability measurements of piezoelectric multilayer actuators comprising stacks 1 that had a first and a second contact element 6, 7 each having a wire fabric in accordance with exemplary embodiment A as metal composite as contact-connection, ceramic faults were no longer manifested as far as the cycle range of 5×10⁸. Consequently, by increasing the tensile strength and elongation at break it is advantageously possible to avoid damage to the piezoelectric layers of the stack.

The failure rate, now produced principally in the overload range of more than 2.0%, is determined at most still by screen cracks.

The contact-connection with a wire fabric in accordance with exemplary embodiment B, in particular the increase in the tensile yield point and tensile strength, has proved to be particularly advantageous with regard to durability. In this case, the wire fabric comprising the wire material in accordance with exemplary embodiment B advantageously builds on the positive properties of the wire fabric in accordance with exemplary embodiment A.

In particular, it was possible to show in experiments that, in the case of the piezoelectric multilayer actuator described here, damage to the piezoelectric layers by cracks can be avoided, which is primarily attributed to the increased elongation at break and the increased tensile strength.

Furthermore, it was possible to show that, by extending the elongation range in which the wire material reacts reversibly to the action of force, screen cracks can be avoided.

The invention is not restricted to the exemplary embodiments by the description on the basis of said exemplary embodiments, but rather encompasses any novel feature and also any combination of features. This includes, in particular, any combination of features in the patent claims, even if this feature or this combination itself is not explicitly specified in the patent claims or exemplary embodiments.

1-15. (canceled)

16. A piezoelectric multilayer actuator comprising:
a stack composed of piezoelectric layers arranged one above another and first electrode layers and second electrode layers arranged between said piezoelectric layers;
wherein the first electrode layers extend into the stack from a first side area of the stack and the second electrode layers extend into the stack from a second side area of the stack;
wherein the first electrode layers and the second electrode layers overlap in the stack;
wherein a first contact element is arranged on the first side area in electrical contact with the first electrode layers and a second contact element is arranged on the second side area in electrical contact with the second electrode layers;
wherein the first and second contact elements each have a wire fabric; and
wherein at least one wire fabric has a twill weave.

17. The multilayer actuator according to claim 16, wherein the at least one wire fabric comprises a material having a tensile yield point of greater than or equal to 380 N/mm².

18. The multilayer actuator according to claim 16, wherein the at least one wire fabric comprises a material having a tensile strength of greater than or equal to 500 N/mm².

19. The multilayer actuator according to claim 16, wherein the at least one wire fabric comprises a material having an elongation at break of greater than or equal to 20%.

20. The multilayer actuator according to claim 16, wherein the at least one wire fabric comprises a material having a coefficient of thermal expansion of greater than or equal to 1.1×10⁻⁵.

21. The multilayer actuator according to claim 16, wherein the at least one wire fabric comprises a material having a modulus of elasticity of approximately 200000 MPa.

22. The multilayer actuator according to claim 16, wherein the at least one wire fabric has a mesh width of greater than or equal to 0.1 mm and less than or equal to 0.3 mm.

23. The multilayer actuator according to claim 16, wherein the at least one wire fabric comprises a material having a wire thickness of greater than or equal to 0.03 mm and less than or equal to 0.3 mm.

24. The multilayer actuator according to claim 16, wherein the at least one wire fabric has a ratio of wire thickness to mesh width in a range of between 0.3 and 0.45.

25. The multilayer actuator according to claim 16, wherein the at least one wire fabric has a mesh width and the ratio of the mesh width to a distance between two first electrode layers directly adjacent to one another is in a range of between 2.5 and 3.5.

26. The multilayer actuator according to claim 16, wherein the at least one wire fabric comprises an austenitic stainless steel or a nickel-chromium alloy.

27. The multilayer actuator according to claim 26, wherein the at least one wire fabric comprises a nickel-chromium alloy having a ratio of nickel to chromium of 80 to 20.

28. The multilayer actuator according to claim 16, wherein the first and second contact elements are embodied identically.

29. The multilayer actuator according to claim 16,
wherein a first electrical contact layer arranged on the first side area and a second electrical contact layer is arranged on the second side area; and
wherein the first contact element is soldered on the first electrical contact layer and the second contact element is soldered on the second electrical contact layer.

30. The multilayer actuator according to claim 16, further comprising a contact pin for further contact-making integrated into the at least one wire fabric.
